(19) United States
(12) Patent Application Publication
(10) Pub. No.: US 2026/0043996 A1
(43) Pub. Date: Feb. 12, 2026

(54) INDIVIDUAL MIRROR FOR A FACETED MIRROR OF AN ILLUMINATION OPTICAL UNIT OF A PROJECTION EXPOSURE SYSTEM

(71) Applicant: Carl Zeiss SMT GmbH, Oberkochen (DE)

(72) Inventors: Ralf AMELING, Aalen (DE); Johannes EISENMENGER, Ulm (DE)

(21) Appl. No.: 19/361,920

(22) Filed: Oct. 17, 2025

Related U.S. Application Data
(63) Continuation of application No. PCT/EP2024/061036, filed on Apr. 23, 2024.

(30) Foreign Application Priority Data
Apr. 25, 2023 (DE) 10 2023 203 810.2

(51) Int. Cl. G02B 26/08; G03F 7/00

(52) U.S. Cl. CPC G02B 26/0833; G03F 7/70075; G03F 7/70116; G03F 7/70825

(57) ABSTRACT

A pivotably mounted individual mirror for a facet mirror of an illumination optics unit of a projection exposure apparatus has a direction-dependent pivot range.

### CROSS-REFERENCE TO RELATED APPLICATIONS

The present application is a continuation of, and claims benefit under 35 USC 120 to, international application No. PCT/EP2024/061036, filed Apr. 23, 2024, which claims benefit under 35 USC 119 of German Application No. 10 2023 203 810.2, filed Apr. 25, 2023. The entire disclosure of each of these applications is incorporated by reference herein.

### FIELD

The disclosure relates to an individual mirror for a facet mirror, such as a field facet mirror or a pupil facet mirror, of an illumination optics unit in a microlithographic projection exposure apparatus. The disclosure further relates to a facet mirror, such as a field facet mirror or a pupil facet mirror, for an illumination optics unit in a projection exposure apparatus, and to an illumination optics unit and an illumination system having such a facet mirror. The disclosure also relates to an optical system for a projection exposure apparatus having such a facet mirror and to a corresponding projection exposure apparatus. In addition, the disclosure relates to a method for producing a microstructured or nanostructured component and also to a component produced according to the method.

### BACKGROUND

For example, a mirror array comprising a multiplicity of displaceable individual mirrors is known from WO 2010/049 076 A2. Actuators are provided for the displacement of the individual mirrors.

### SUMMARY

The present disclosure seeks to provide an improved displaceable individual mirror for a facet mirror of an illumination optics unit in a microlithographic projection exposure apparatus, and also to provide assemblies and subsystems of a corresponding projection exposure apparatus having one or more such individual mirrors.

The disclosure includes developing an individual mirror with a mount for pivotable bearing of the mirror body with two degrees of tilt freedom and an actuator device for pivoting the mirror body in such a way that the mirror body has a direction-dependent tilt angle range. To this end, the mount and/or the actuator device for example may have direction-dependent properties. The terms “direction-dependent” and “non-isotropic” refer here and below to the azimuthal tilt direction.

This can allow the individual mirror to be adapted to specific desired properties in a targeted manner. As a result, certain characteristics of the individual mirror can be improved, such as its thermal resistance.

According to the disclosure, it was recognized that the desired properties related to the maximum tilt range for two tilt axes, which may be perpendicular to each other for example, often vary in size.

The tilt angles or the tilt angle range may be the maximum achievable tilt angles of the individual mirror, the tilt angles that can be generated by applying a certain force or a certain torque, or the tilt angles that can actually be generated with the actuator device.

For example, the tilt angle range might not be isotropic.

For example, the maximum possible tilt angle, such as the maximum tilt angle that can be generated by the action of on a certain force on the mirror body, and/or the maximum tilt angle that can be generated with the actuator device may be direction dependent.

For example, the tilt angle range might be elliptical. This is understood to mean that a curve that represents the desired two-dimensional tilt angle range of the individual mirror or a curve that represents the actual two-dimensional tilt angle range of the individual mirror, such as when a certain force or when the maximum force or the maximum torque that can be generated by the actuator device is applied to the curve, has an elliptical shape or shape that is elliptical at least to a first approximation.

The tilt angle range may have such an asymmetric direction-dependence that the tilt angles about two pivot axes of the individual mirror, such as the tilt angles about two pivot axes that are defined by the mount of the individual mirror and are perpendicular to each other for example, have a ratio of at least 1.05, such as at least 1.1, for example at least 1.2, for example at least 1.3.

According to an aspect, the mount is designed such that a stiffness of the mount with regard to a pivoting of the mirror body about a first pivot axis is greater than a stiffness of the mount with regard to a pivoting of the mirror body about a second pivot axis.

In this case, the second pivot axis may for example be oriented perpendicular to the first pivot axis. It may also make an angle of 60° with the first pivot axis.

The stiffness of the mount with regard to the pivot of the mirror body about a first pivot axis may be greater than the stiffness of the mount with regard to the pivot of the mirror body about the second pivot axis by at least 3%, such as by at least 5%, for example by at least 10%, for example by at least 20%, for example by at least 30%.

According to an aspect, the mount may comprise springs with different stiffnesses.

Where different sizes are mentioned in this application, these sizes may in each case deviate from each other by at least 3%, such as by at least 5%, for example by at least 10%, for example by at least 20%, for example by at least 30%. The relative difference is usually less than one order of magnitude, such as less than a factor of 10, for example less than a factor of 5, for example less than a factor of 3.

The springs might be torsion springs and/or leaf springs.

For example, the springs may have different widths and/or different thicknesses and/or different lengths.

This can help allow the mechanical, thermal and electrical properties of the springs to be easily influenced.

According to an aspect, the mount comprises springs made of different materials.

For example, it is possible to form a first spring from a first material and a second spring from a second material, with the first material and the second material not being identical.

The mechanical and thermal properties of the springs may be influenced by the choice of materials.

According to an aspect of the disclosure, at least one spring element assigned to an axis with lower desired tilt angle properties, for example all such spring elements, is (are) made from a material having a higher shear modulus and/or a higher Young's modulus and/or a simultaneously higher thermal conductivity and/or a higher electrical conductivity than at least one spring element, for example all spring elements, assigned to an axis with higher desired tilt angle properties.

According to a further aspect, the mount comprises springs with different coatings.

The mechanical and/or thermal properties of the springs may be influenced by a coating.

Different coatings should be understood to mean that a first spring has a first coating, and a second spring has a second coating, with the first coating not being identical to the second coating. The difference may lie in the material of the coating and/or in the details of the application. Different coatings should also be understood to mean that one spring has a coating, and another spring has no coating.

According to a further aspect, the actuator device is designed such that the maximum torque that can be generated with the actuator device and is applied to the mirror body is greater with regard to a first pivot axis than with regard to a second pivot axis.

As regards the differences, reference should be made to the description above.

The pivot axes may be perpendicular to each other for example. They may also make an angle of 60° with each other. This information should not be understood to be restrictive.

It has been recognized that a reduction in the maximum torque that can be generated may lead to a simplification with regard to the design of the actuator device.

According to a further aspect, the actuator device comprises actuator elements that are arranged in such a way that they have an irregular distribution.

This also can help allow a direction-dependent maximum torque to be achieved.

Electrodes, such as in the form of comb fingers, can serve as actuator elements. The electrodes may be arranged in an annular region for example. For example, they may extend radially with respect to a central axis, such as through the intersection of the pivot axes of the mirror body.

The actuator elements, such as the electrodes, may have a different angular distribution for example.

The actuator elements, such as the electrodes, may for example have different, i.e. azimuthally varying, spacings. In particular, this should be understood to mean that there are at least two pairs of adjacent actuator elements, such as electrodes, with different spacings.

According to a further aspect, the actuator device comprises differently designed actuator elements.

The actuator device may for example comprise electrodes, such as comb fingers, with different lengths and/or different heights and/or different geometries.

This can help allow the torque that can be generated by the actuator device to be influenced.

According to a further aspect, the actuator device comprises a different number of actuator elements, such as electrodes, for example comb fingers, for different pivot directions.

For example, the number of comb fingers assigned to a first pivot axis may be greater than the number of comb fingers assigned to a second pivot axis by at least 2, such as by at least 5, for example by at least 10.

The actuator elements, such as the electrodes, for example the comb fingers, may be uniformly distributed and equidistantly arranged. They may also have an irregular distribution.

According to a further aspect, the actuator device and mount are adapted to each other.

For example, the maximum torque that can be generated with the actuator device may be adapted in a certain direction to the stiffness of the mount and to the desired maximum tilt angle in this direction.

According to a further aspect, the individual mirror may be designed as MEMS (microelectromechanical system) or MOEMS (microoptoelectromechanical system).

The individual mirror may be designed as a micromirror for example. It may have a reflection surface of no more than 1 mm².

The individual mirror may have a reflection surface with a maximum side length or a maximum diameter of no more than 2 mm, such as no more than 1 mm, for example no more than 600 μm, for example no more than 400 μm.

The reflection surface of the individual mirror may be polygonal and regular for example. The reflection surface of the individual mirror may also be formed as an irregular polygon.

The reflection surface of the individual mirror may have a triangular, quadrilateral or hexagonal design.

The reflection surface of the individual mirror may be in the form of a tile. This should be understood to mean that the reflection surface of the individual mirror is designed in such a way that it allows a substantially seamless tessellation in a plane.

According to a further aspect, the individual mirror may be constructed according to the shadow casting principle. This should be understood to mean that the electrical, electronic and mechanical constituent parts of the individual mirror are arranged in a cylindrical volume, the reflection surface of the individual mirror forming a generatrix of this cylindrical volume. It may be an oblique cylinder. It can be a right cylinder. The volume may be a prism-shaped volume, such as a cuboid volume.

A further aspect may provide for the combination of a plurality of individual mirrors to form a mirror module. The mirror module may be a mechanical unit for example.

This can help facilitate the handling of individual mirrors, for example in the event of a large number of individual mirrors. In these mirror modules, the substructure containing the common electronics and also the cooling may have a cylindrical shape with a relatively large height-to-side ratio.

With regard to the details of the actuator and/or sensor device, such as the electrodes thereof, reference is made to DE 10 2015 204 874 A1.

The disclosure also relates to a facet mirror for an illumination optics unit in a projection exposure apparatus having a plurality of individual mirrors, with at least one non-empty subset of the individual mirrors being designed according to the preceding description.

For example, at least 10%, such as at least 20%, for example at least 30%, for example at least 50%, for example at least 70%, for example all, of the individual mirrors may be designed according to the preceding description.

The directional dependence of the tilt angle ranges of the individual mirrors may be organized in groups. For example, it may be identical on a groupwise basis. This should be understood to mean that groups of individual mirrors have the same directional dependence. The individual mirrors of a group are arranged in a simply connected region for example, with for example no mirrors that do not belong to this group being arranged in this region.

The directional dependence of the individual mirrors may also vary systematically over the total extent of the facet mirror. For example, it can be represented as a function of the position of the individual mirror on the facet mirror. For example, this may be a continuous function, such as a differentiable function.

It is also possible to choose the tilt angle range of the individual mirrors and for example the directional dependence thereof for at least a subset of the individual mirrors on an individual basis, such as for all the individual mirrors.

The facet mirror may be a field facet mirror or a pupil facet mirror. The facet mirror may also be provided for arrangement in a plane that is conjugate neither to a field plane nor to a pupil plane.

According to a further aspect, at least two of the individual mirrors, such as at least two different groups of the individual mirrors, have different pre-tilts.

This can help allow desired asymmetric tilt angle properties to be addressed.

The phrase different pre-tilts is understood to mean that, in particular, the normals of the reflection surfaces of the individual mirrors, in particular the surface normals, through a central point of the reflection surface of the individual mirrors, have the same different orientations in the neutral, non-pivoted state.

The individual mirrors may be arranged on carriers in groupwise fashion for example. By tilting such a carrier, a groupwise pre-tilt of the individual mirrors can be achieved in a relatively simple way. A wedge-shaped mirror body can also be used to realize a pre-tilt of the reflecting mirror surface.

The pre-tilt of the individual mirrors may be adjustable.

For example, it is possible to design the tilt of the carrier for the individual mirrors to be adjustable, such as mechanically adjustable.

The disclosure also relates to an illumination optics unit for a projection exposure apparatus having at least one facet mirror, such as two facet mirrors, according to the preceding description.

Such an illumination optics unit can allow for relatively flexible setting of different illumination settings.

The disclosure also relates to an illumination system for a projection exposure apparatus and such an illumination optics unit and a radiation source for generating illumination radiation. For example, the radiation source may be an EUV radiation source for generating illumination radiation in the EUV range.

The disclosure also relates to an optical system for a projection exposure apparatus comprising an illumination optics unit according to the preceding description and a projection optics unit for imaging a reticle arranged in an object field onto a wafer arranged in an image field.

Furthermore, the disclosure relates to a microlithographic projection exposure apparatus having such an optical system and a radiation source for generating illumination radiation, such as in the EUV range.

In addition, the disclosure relates to a method for producing a microstructured or nanostructured component and also to a component produced according to the method.

By providing a projection exposure apparatus according to the previous description, a corresponding method and the components produced thereby can be improved.

### BRIEF DESCRIPTION OF THE DRAWINGS

Further features, details and particulars of the disclosure are evident from the description of exemplary embodiments with reference to the drawings, in which:

FIG. 1 shows a schematic illustration of a projection exposure apparatus and its constituent parts;

FIG. 2 schematically shows a cross section through a displaceable individual mirror;

FIG. 3 shows a partial illustration of an individual mirror with constituent parts of an actuator device for displacing the individual mirror;

FIG. 4 schematically depicts an exemplary embodiment of the actuator device;

FIG. 5 schematically shows a plan view of some of the actuator electrodes for displacing an individual mirror;

FIG. 6 schematically shows a view according to FIG. 5 of an alternative arrangement of the actuator electrodes;

FIG. 7 schematically shows a further variant of the arrangement of the actuator electrodes;

FIG. 8 shows an illustration of an embodiment of a flexure for tiltably bearing an individual mirror by way of example; and

FIG. 9 schematically shows a variant of the flexure according to FIG. 8.

### EXEMPLARY EMBODIMENTS

Firstly, the general structure of a projection exposure apparatus 1 and the constituent parts thereof will be described. For details in this regard, reference should be made to WO 2010/049 076 A2, which is hereby fully incorporated in the present application as part thereof. The description of the general structure of the projection exposure apparatus 1 should only be understood to be exemplary. It serves to explain a possible application of the subject matter of the present disclosure. The subject matter of the present disclosure may also be used in other optical systems, such as in alternative variants of projection exposure apparatuses. For example, the tilt mirror concept described hereinafter is not restricted to the structure of the projection exposure apparatus 1, depicted in exemplary fashion, or the constituent parts thereof. For example, its application is not restricted to the specific MEMS design presented in exemplary fashion in this context.

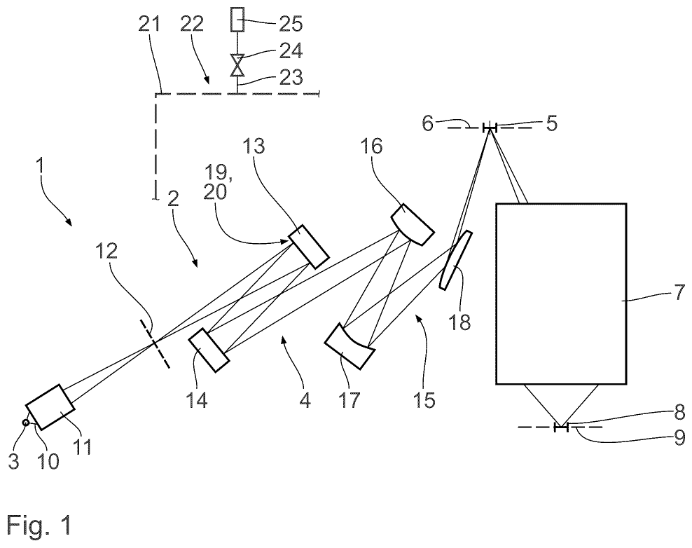

FIG. 1 schematically shows a microlithographic projection exposure apparatus 1 in a meridional section. An illumination system 2 of the projection exposure apparatus 1 has, besides a radiation source 3, an illumination optics unit 4 for the exposure of an object field 5 in an object plane 6. The object field 5 can have a rectangular or arcuate design with an x/y-aspect ratio of 13/1, for example. In this case, a reflective reticle (not depicted in FIG. 1) arranged in the object field 5 is exposed, the reticle bearing a structure to be projected by the projection exposure apparatus 1 for the production of microstructured or nanostructured semiconductor components. A projection optics unit 7 serves for imaging the object field 5 into an image field 8 in an image plane 9. The structure on the reticle is imaged onto a light-sensitive layer of a wafer, which is not depicted in the drawing and is arranged in the region of the image field 8 in the image plane 9.

The reticle, which is held by a reticle holder (not depicted here), and the wafer, which is held by a wafer holder (not depicted here), are scanned synchronously in the y-direction during the operation of the projection exposure apparatus 1. Depending on the imaging scale of the projection optics unit 7, it is also possible for the reticle to be scanned in the opposite direction relative to the wafer.

The radiation source 3 is an EUV radiation source with emitted used radiation in the range of between 5 nm and 30 nm. This may be a plasma source, for example a GDPP (Gas Discharge Produced Plasma) source or an LPP (Laser Produced Plasma) source. Other EUV radiation sources, for example those based on a synchrotron or on a free electron laser (FEL), are also possible.

EUV radiation 10 emerging from the radiation source 3 is focused by a collector 11. A corresponding collector is known for example from EP 1 225 481 A2. Downstream of the collector 11, the EUV radiation 10 propagates through an intermediate focal plane 12 before being incident on a field facet mirror 13. The field facet mirror 13 is arranged in a plane of the illumination optics unit 4 optically conjugate to the object plane 6. The field facet mirror 13 may be arranged at a distance from a plane that is conjugate to the object plane 6. In this case, it is generally referred to as a first facet mirror.

The EUV radiation 10 is also referred to hereinafter as used radiation, illumination radiation or imaging light.

Downstream of the field facet mirror 13, the EUV radiation 10 is reflected off a pupil facet mirror 14. The pupil facet mirror 14 is located either in the entrance pupil plane of the projection optics unit 7 or in a plane optically conjugate thereto. It may also be arranged at a distance from such a plane.

The field facet mirror 13 and the pupil facet mirror 14 are constructed from a multiplicity of individual mirrors, which will still be described in detail below. In this case, the subdivision of the field facet mirror 13 into individual mirrors can be such that each of the field facets illuminating the entire object field 5 by themselves is represented by exactly one of the individual mirrors. Alternatively, it is possible to construct at least some or all of the field facets using a plurality of such individual mirrors. The same correspondingly applies to the configuration of the pupil facets of the pupil facet mirror 14, which are each assigned to the field facets and each of which may be formed by a single individual mirror or by a plurality of such individual mirrors.

The EUV radiation 10 is incident on both facet mirrors 13, 14 at a defined angle of incidence. For example, the two facet mirrors are exposed to EUV radiation 10 in the range associated with normal incidence operation, i.e. at an angle of incidence that is less than or equal to 25° in relation to the mirror normal. Exposure to grazing incidence is also possible. The pupil facet mirror 14 is arranged in a plane of the illumination optics unit 4 that constitutes a pupil plane of the projection optics unit 7 or is optically conjugate to a pupil plane of the projection optics unit 7. With the aid of the pupil facet mirror 14 and—optionally—an imaging optical assembly in the form of a transfer optics unit 15 which has mirrors 16, 17 and 18 designated in the order of the beam path for the EUV radiation 10, the field facets of the field facet mirror 13 are imaged into the object field 5 in a manner superimposed on one another. The last mirror 18 of the transfer optics unit 15 is a mirror for grazing incidence (“grazing incidence mirror”). The transfer optics unit 15 together with the pupil facet mirror 14 is also referred to as a sequential optics unit for transferring the EUV radiation 10 from the field facet mirror 13 toward the object field 5. The illumination light 10 is guided from the radiation source 3 toward the object field 5 via a plurality of illumination channels. Each of these illumination channels is assigned a field facet of the field facet mirror 13 and a pupil facet of the pupil facet mirror 14, the pupil facet being disposed downstream of the field facet. The individual mirrors of the field facet mirror 13 and of the pupil facet mirror 14 can be tiltable by an actuator system, such that a change in the assignment of the pupil facets to the field facets and correspondingly a modified configuration of the illumination channels can be achieved. This results in different illumination settings, which differ in the distribution of the illumination angles of the illumination light 10 over the object field 5.

Different illumination settings may be achieved by tilting the individual mirrors of the field facet mirror 13 and correspondingly modifying the assignment of the individual mirrors of the field facet mirror 13 to the individual mirrors of the pupil facet mirror 14. Depending on the tilt of the individual mirrors of the field facet mirror 13, the individual mirrors of the pupil facet mirror 14 that are newly assigned to the individual mirrors are updated by tilting such that imaging the field facets of the field facet mirror 13 into the object field 5 is once again ensured.

Further aspects of the illumination optics unit 4 are described below.

The one field facet mirror 13 in the form of a multi- or micro-mirror array (MMA) forms an example of an optical assembly for guiding the used radiation 10, i.e. the EUV radiation beam. The field facet mirror 13 is in the form of a microelectromechanical system (MEMS). It comprises a multiplicity of individual mirrors 20 arranged in a mirror array in a matrix-like manner in rows and columns. The mirror arrays have a modular embodiment. They can be arranged on a load-bearing structure that is embodied as a base plate. Here, it is possible to arrange substantially any number of the mirror arrays next to one another. Consequently, the overall reflection surface formed by the totality of all mirror arrays, such as by the individual mirrors 20 thereof, is extendable as desired. For example, the mirror arrays are embodied in such a way that they enable a substantially gap-free tessellation of a plane. The ratio of the sum of the reflection surfaces 26 of the individual mirrors 20 to the overall surface area covered by mirror arrays is also referred to as integration density. For example, this integration density is at least 0.5, such as at least 0.6, for example at least 0.7, for example at least 0.8, for example at least 0.9.

The individual mirrors 20 are designed to be tiltable by way of an actuator. For details, reference is made to WO 2012/130 768 A2, for example. Overall, the field facet mirror 13 contains approximately 100 000 of the individual mirrors 20. The field facet mirror 13 may also have a different number of individual mirrors 20 depending on the size of the individual mirrors 20. The number of individual mirrors 20 of the field facet mirror 13 can be at least 1,000, such as at least 5,000, for example at least 10,000. It may be up to 100,000, such as up to 300,000, for example up to 500,000, for example up to 1,000,000.

A spectral filter may be arranged upstream of the field facet mirror 13 and separates the used radiation 10 from other wavelength components of the emission of the radiation source 3 that are not usable for the projection exposure. The spectral filter is not depicted here.

The entire individual mirror array of the facet mirror 13 has, for example, a diameter of 500 mm and is designed to be closely packed with the individual mirrors 20. Insofar as a field facet is realized by exactly one individual mirror in each case, the individual mirrors 20 represent the shape of the object field 5, apart from a scaling factor. The facet mirror 13 may be formed by 500 individual mirrors 20 which each represent a field facet and have a dimension of approximately 5 mm in the y-direction and 100 mm in the x-direction. As an alternative to the realization of each field facet by exactly one individual mirror 20, each of the field facets can be approximated by groups of smaller individual mirrors 20, such as micromirrors. A field facet having dimensions of 5 mm in the y-direction and of 100 mm in the x-direction may be constructed e.g. using a 1×20 array of individual mirrors 20 with dimensions of 5 mm×5 mm, through to a 10×200 array of individual mirrors 20 with dimensions of 0.5 mm×0.5 mm.

The tilt angles of the individual mirrors 20 are adjusted for the purpose of changing the illumination settings. For example, the tilt angles have a displacement range of ±50 mrad, such as ±100 mrad, for example ±200 mrad. An accuracy of better than 0.2 mrad, such as better than 0.1 mrad, is achieved within the scope of setting the tilt position of the individual mirrors 20.

The individual mirrors 20 of the field facet mirror 13 and of the pupil facet mirror 14 in the embodiment of the illumination optics unit 4 according to FIG. 1 bear multilayer coatings for the purpose of optimizing their reflectivity at the wavelength of the used radiation 10. This is achieved by a suitable structure of the individual mirrors 20. For details, reference is made to DE 10 2013 206 529 A1, which is hereby fully incorporated into the present application.

The individual mirrors 20 of the illumination optics unit 4 are accommodated in an evacuable chamber 21, a boundary wall 22 of which is indicated in FIG. 1. The chamber 21 communicates with a vacuum pump 25 via a fluid line 23, in which a shut-off valve 24 is accommodated. The operating pressure in the evacuable chamber 21 is a few pascals.

Together with the evacuable chamber 21, the mirror comprising the plurality of individual mirrors 20 forms an optical assembly for guiding and/or shaping a beam of the EUV radiation 10.

Each of the individual mirrors 20 may have a reflection surface 26 with dimensions of 0.1 mm×0.1 mm, 0.5 mm×0.5 mm, 0.6 mm×0.6 mm, or else of up to 5 mm×5 mm or larger. The reflection surface 26 may also have smaller dimensions. For example, it has side lengths in the um range or low mm range. The individual mirrors 20 are therefore also referred to as micromirrors.

The reflection surface 26 is part of a mirror body 27 of the individual mirror 20. The mirror body 27 carries the multilayer coating. The mirror body 27 may for example be produced from, for example comprise or consist of, a semiconductor material, such as silicon, or a semiconductor compound, for example a silicon compound.

For the lithographic production of a microstructured or nanostructured component, such as a semiconductor component, e.g. a microchip, at least one part of the reticle is imaged onto a region of a light-sensitive layer on the wafer with the aid of the projection exposure apparatus 1. Depending on the embodiment of the projection exposure apparatus 1 as a scanner or as a stepper, the reticle and the wafer are moved in the y-direction in a manner synchronized in time, continuously in scanner operation or step by step in stepper operation.

Further details and aspects of the mirror array 19, such as of the optical components which comprise the individual mirrors 20, are described below.

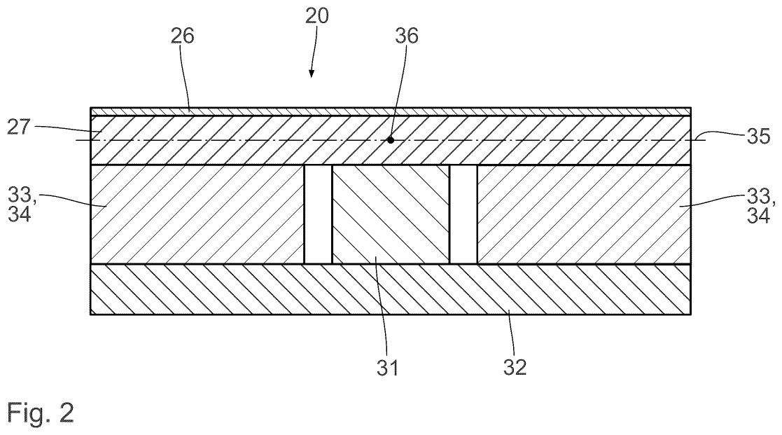

FIG. 2 schematically shows the structure, such as the bearing, of the individual mirror 20.

The mirror body 27 is mounted on a carrier 32 via a mount 31. The carrier 32 is also referred to as a substrate or load-bearing plate.

An actuator device 33 and a sensor device 34 are arranged in the region behind the mirror body 27, for example in the region between the mirror body 27 and the carrier 32. The individual mirror 20 is rendered movable, for example tiltable, via the actuator device 33. For example, it can be tilted about two tilt axes 35, 36. The individual mirror 20 has two degrees of tilt freedom for example.

The individual mirror 20 is tiltable, such as in controlled fashion, for example in regulated fashion.

In respect of exemplary details with regard to the bearing of the individual mirror 20, reference is made to DE 10 2015 204 874 A1.

In addition to mechanical bearing of the individual mirror 20, the mount 31 serves to allow the dissipation of a thermal load that arises due to the incident EUV radiation 10, such as the dissipation thereof to the carrier 32.

The mount 31 may also be used to establish an electrically conductive connection between the mirror body 27 and/or sensors and/or actuators above the mount 31 and an electrical contact below the mount, for example in the region of the carrier 32. According to the disclosure, it was recognized that a design of the mount 31 in which the desired direction-dependent properties for the tilt angle range are exploited in such a way that the thermal and electrical resistance are reduced as much as possible can leads to advantages.

Further, provision can be made for an adaptation of the actuator device 33 and the design of the mount 31. This is desirable, for example in the case of a radial comb electrode tilt actuator, as will still be described in detail below.

The actuator device 33 and/or the sensor device 34 can be arranged completely below the mirror body 27, for example in a cylindrical volume with the reflection surface 26 acting as a generatrix, such as in a prism-shaped volume, and for example a cuboid-shaped volume.

The mount 31 and/or the actuator device 33 and/or the sensor device 34, such as all of these elements, may be realized as a microelectromechanical system (MEMS). For example, they may have a layer-like structure.

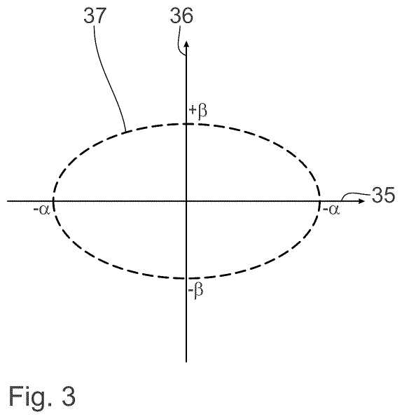

According to the disclosure, it was recognized that the desired properties for the two-dimensional tilt angle range of the individual mirror 20 need not be isotropic. For example, the maximum tilt angle to be achieved may depend on the direction. This is illustrated in FIG. 3 by way of example. Here, the tilt angle range about the first tilt axis 35 is plotted on the x-axis. The y-axis indicates the tilt angle range of the individual mirror 20 about the second tilt axis 36.

In FIG. 3, a feature 37 for two-dimensional tilt angle range of the individual mirror 20 is shown by way of example.

In the example shown in FIG. 3 by way of example, the two-dimensional tilt angle range of the individual mirror 20 has an elliptical form. This should be understood as non-limiting.

In an alternative to an elliptical embodiment, the tilt angle range may also be rectangular for example.

For example, the two tilt axes 35, 36 may lie parallel to the two semi-axes of the ellipse or parallel to the sides of the rectangle.

The mount 31 may comprise a flexure for example. For example, the mount 31 may comprise one or more torsion beams or torsion springs or leaf springs 38. An exemplary embodiment of the leaf springs is depicted in FIG. 8. The leaf springs 38 form a two-dimensional tilt joint.

The dimensions and materials of the leaf springs 38 can be adapted to the tilt angle range of the individual mirror 20 for each of desired properties for the tilt axes 35, 36. A corresponding adaptation is also possible for the design of the constituent parts of the actuator device 33 for each of the tilt directions.

The adaptation may be designed such that the combination of the reversing torque of the mount 31 and the driving torque of the actuator device 33 allows the maximum desired tilt angle to be reached, with, for example simultaneously, a thermal and/or electrical resistance of the mount 31 being reduced as far as possible.

In the case of torsion springs (not depicted here), this may be achieved by virtue of the fact that the spring elements assigned to the axis with the lower desired properties for tilt angle are shorter and/or thicker and/or wider than the spring elements assigned to the axis with the greater desired properties for tilt angle.

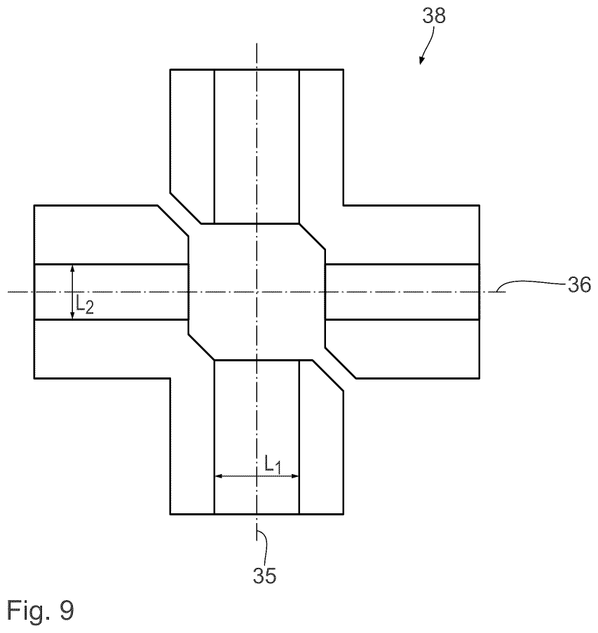

In the case of leaf springs 38, this may be achieved by virtue of the spring elements assigned to the axis with the lower desired properties for tilt angle being shorter and/or thicker and/or wider than the spring elements assigned to the axis with the greater desired properties for tilt angle. This is illustrated by way of example in FIG. 9. In this variant, the spring elements assigned to the second tilt axis 36 have a shorter spring length L2 than the spring elements assigned to the first tilt axis 35, which have a spring length L1.

The mechanical and/or thermal and/or electrical properties of the spring elements can also be influenced by a coating.

A further option for influencing the stiffness of the mount 31, for example of the leaf springs 38, lies in the selection of materials for the same. Spring elements assigned to the axis with the lower desired properties for tilt angle may be made of a material having a higher shear modulus and/or a higher Young's modulus. They may simultaneously have greater thermal conductivity and/or a greater electrical conductivity than the spring elements assigned to the axis with the greater desired properties for tilt angle.

If the desired properties for tilt angle for a given axis are asymmetrical, for example deviate from each other in the positive and negative directions, the previously described adjustment of the spring elements may be combined with a pre-tilt of the mirror body 27 by a fixed tilt angle. For example, the pre-tilt might be achieved by tilting the carrier 32.

The pre-tilt may be adjustable.

In the case of leaf springs 38, provision may be made for the length and/or the width and/or thickness of the springs, i.e. their shape in general, to be adapted in such a way that the springs or a combination of the springs are or is relatively stable with regard to their transverse stiffness, i.e. with regard to their mechanical stiffness in relation to undesirable movements. This allows parasitic tilts to be kept as small as possible. In this context, parasitic tilts are tilts about an axis that are not parallel to the applied torque and/or perpendicular to the applied force.

Parasitic tilt and translation movements can be kept as small as possible. This can be desirable in the context of an actuator device 33 with comb electrodes, for example with parallel oriented comb fingers or with radially oriented comb electrodes. This may prevent undesirably close approach of the moving electrodes 39 and the stator electrodes 40. In turn, this may prevent the actuator torque from being too dependent on the tilt angle at a given actuator voltage, i.e. from varying greatly with the meshing and separation of the combs. As a result, the control of the positioning of the individual mirror 20 may be improved, for example at larger tilt angles.

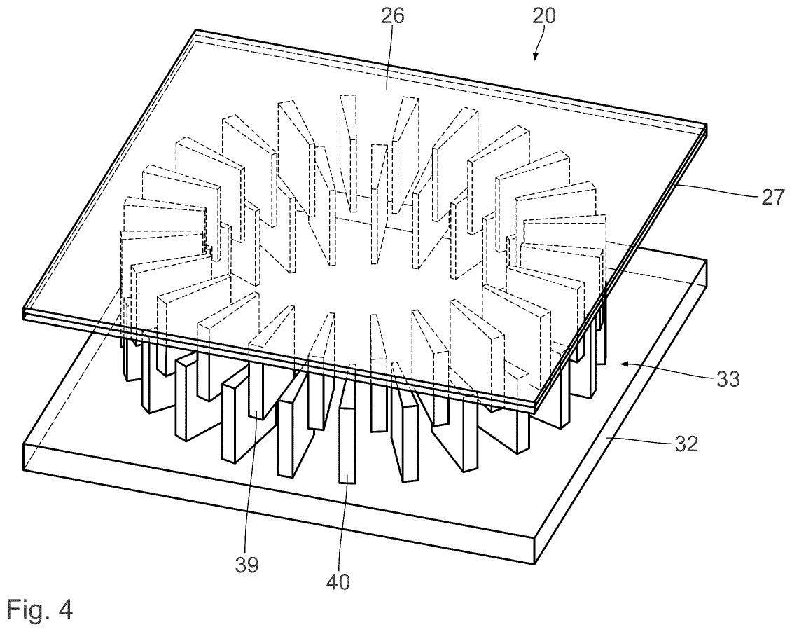

FIG. 4 schematically depicts an exemplary embodiment of the actuator device 33. In this variant, the actuator device 33 comprises a multiplicity of electrodes 39, 40. The electrodes 39, 40 are designed in the form of comb fingers. For example, they are radially oriented. For example, they are arranged in a circular region.

The sensor device 34 may be embodied accordingly.

The electrodes 39 are connected to the mirror body 27. They thus move together with the mirror body 27 in the event of a displacement of the individual mirror 20. They are therefore also referred to as movable electrodes 39.

The electrodes 40 are connected to the carrier 32. For example, they form stator electrodes.

The individual mirror 20 that can be tilted about the first tilt axis 35 and the second tilt axis 36 may for example comprise four actuator elements, for example in the form of electrode groups. The actuator torques used for a tilt of the individual mirror 20 about the two tilt axes 35, 36 can be generated via the actuator elements.

For example, the individual actuator elements can be adapted to the direction-dependent tilt angle range by way of a distribution, for example an irregular distribution, of the installation space for the individual actuator elements.

In the case of a piezoelectric bending actuator, the individual actuator elements may be realized on bending beams of different lengths and/or widths.

In the case of a capacitive comb actuator, the individual actuator elements may be assigned electrodes of different lengths and/or different numbers of comb electrode fingers.

In the case of a radial comb electrode tilt actuator, as illustrated in FIG. 4 by way of example, the actuator elements can be adapted to the direction-dependent tilt angle range by way of a variation of the spacings between adjacent movable electrodes 39 and/or adjacent stator electrodes 40.

The spacings between adjacent movable electrodes 39 and/or adjacent stator electrodes 40 may vary in a manner dependent on their azimuthal alignment for example.

According to the disclosure, it was recognized that the movable electrodes 39 are increasingly oriented non-parallel to the stator electrodes 40, the more their radial alignment deviates from a perpendicular to the tilt axis. This oblique meshing leads to a strong increase in the actuator torque at large tilt angles and hence decreasing spacings between a movable electrode 39 and the adjacent stator electrodes 40. In order to improve the controllability of the system, the spacing between adjacent electrodes 39, 40 can be chosen to be ever larger with increasing maximum tilt angle about an axis with the corresponding azimuthal orientation. In other words, the greater the maximum tilt angle, the greater the spacing can be chosen for adjacent electrodes 39, 40 which have the same azimuthal orientation as the respective tilt axis.

In the case of an elliptical tilt range (see FIG. 3), provision can be made for example for comb fingers that are oriented perpendicular to the tilt axis with the larger tilt angle range to be arranged with a smaller mutual spacing than comb fingers that are oriented perpendicular to the tilt axis with the smaller tilt angle range.

In the case of an elliptical tilt angle range, the spacing of adjacent electrodes 39, 40 can be varied, for example continuously and for example according to the tilt angle range.

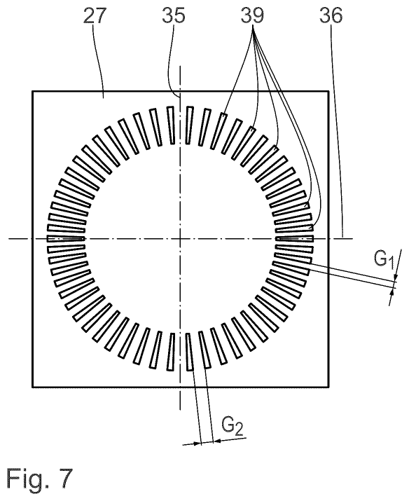

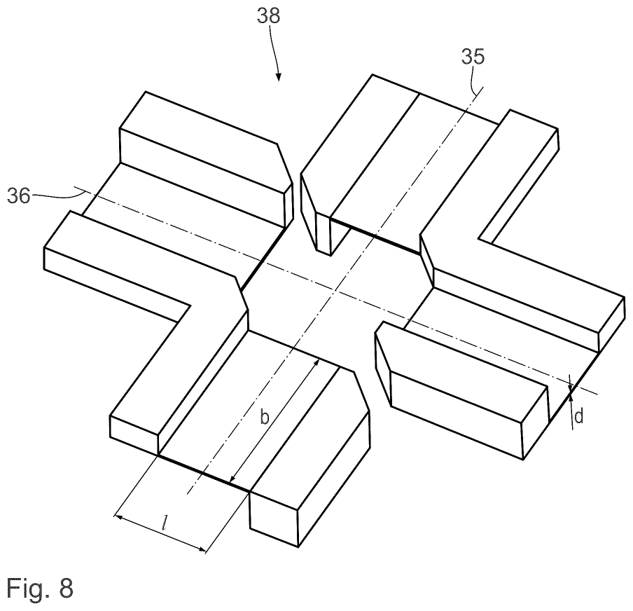

This is illustrated by way of example in FIG. 7. In this variant depicted in exemplary fashion, the electrodes 39 that cause a tilt of the mirror body 27 about the second tilt axis 36 have a greater spacing than the electrodes 39 that cause a tilt of the mirror body 27 about the first tilt axis 35. The same applies to the stator electrodes 40.

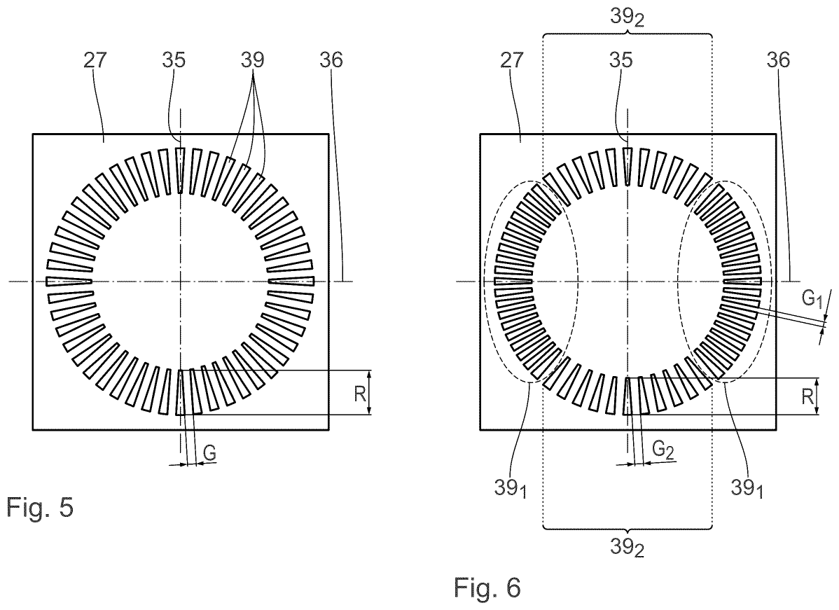

As schematically highlighted in FIG. 5, the embodiment and/or arrangement of the electrodes 39 can be characterized by their spacing G and/or by their length R in the radial direction. The two parameters can be varied independently or in combination.

In the variant depicted in FIG. 6, the electrodes 39₁ that lead to the tilt of the mirror body 27 about the first tilt axis 35 have a smaller spacing G₁ than the electrodes 39₂ that lead to the tilt of the mirror body 27 about the second tilt axis 36. The latter have a spacing of G₂.

The variation of the spacing G of the electrodes 39 and the variation of their length R may be independent of each other. The variations of spacing G and length R may also be combined with each other.

An increase in the spacing G of adjacent electrodes 39 by a factor F1 may lead to a reduction in the actuator torque with respect to the assigned axis by a corresponding factor F₁.

A reduction in the electrode length R by a factor F₂ may lead to a reduction in the actuator torque about the corresponding axis by a corresponding factor F₂.

In the variant shown in FIG. 6 by way of example, the length R of all electrodes 39 was reduced by a factor F₂. At the same time, the spacing G of the electrodes 39₁ was reduced by the factor F₁, which equals F₂. With this combination, the actuator torque remains the same for the first tilt axis 35, while the actuator torque for the second axis 36 is reduced by the factor F₂.

By reducing the electrode length R, the installation space for the actuator device 33 could be reduced at the same time.

The arrangements of the electrodes 39 on the mirror body 27 depicted by way of example in FIGS. 5 to 7 are correspondingly also possible for the embodiment and/or arrangement of the electrodes 40 on the carrier 32.

The arrangement of the electrodes 40 on the carrier 32 can be adapted to the embodiment and arrangement of the electrodes 39 on the mirror body 27.

In the event of the spring elements being embodied as leaf springs, an increase in the rotational stiffness of the mount 31 about a certain axis by a factor S can be achieved by
a) an increase in the width b of the springs by a corresponding factor S,
b) an increase in the thickness d of the springs by a factor VS
c) a reduction in the length 1 of the springs by a factor S,
or a suitable combination of these parameters.

An increase in the width b and/or a reduction in the length 1 of the leaf springs 38 leads to a reduction in the thermal and electrical resistance of the same.

An increase in the spring width B leads to an increased installation space. A reduction of the spring length 1 is therefore usually more desirable, at least for as long as no critical values for the mechanical stresses within the spring are reached in the process.

What is claimed is:

1. A mirror, comprising:
a mirror body;
a mount for pivotable bearing of the mirror body with two degrees of tilt freedom; and
an actuator device configured to pivot the mirror body,
wherein:
the mount and/or the actuator device are configured so that the mirror body has a direction-dependent tilt angle range;
the actuator device comprises a plurality of radially arranged actuator elements; and
the actuator elements have azimuthally varying spacings.

2. The mirror of claim 1, wherein the mount is configured so that the mirror body has the direction-dependent tilt angle range.

3. The mirror of claim 2, wherein the actuator device is configured so that the mirror body has the direction-dependent tilt angle range.

4. The mirror of claim 1, wherein the actuator device is configured so that the mirror body has the direction-dependent tilt angle range.

5. The mirror of claim 1, wherein a stiffness of the mount with regard to a pivoting of the mirror body about a first pivot axis is greater than a stiffness of the mount with regard to a pivoting of the mirror body about a second pivot axis.

6. The mirror of claim 1, wherein the mount comprises springs with different stiffnesses.

7. The mirror of claim 1, wherein the mount comprises springs comprising different materials.

8. The mirror of claim 1, wherein the mount comprises springs comprising different coatings.

9. The mirror of claim 1, wherein a maximum torque generateable via the actuator device and applicable to the mirror body is greater with regard to a first pivot axis than with regard to a second pivot axis which is different from the first pivot axis.

10. The mirror of claim 1, wherein the actuator device comprises actuator elements having an irregular distribution.

11. The mirror of claim 1, wherein the actuator device comprises actuator elements configured for different pivot directions.

12. The mirror of claim 1, wherein the actuator device comprises a different number of actuator elements for different pivot directions.

13. The mirror of claim 1, wherein the actuator device and the mount are adapted to each other.

14. The mirror of claim 1, wherein the individual mirror comprises a microelectromechanical system or a microoptoelectromechanical system.

15. A mirror, comprising:
a plurality of individual mirrors,
wherein at least one of the individual mirrors comprises a mirror according to claim 1, and the mirror is a facet mirror.

16. A mirror comprising:
a plurality of individual mirrors comprising a first individual mirror and a second individual mirror,
wherein:
each of the first and second mirrors comprises a mirror according to claim 1;
the first mirror has a pre-tilt that is different from a pre-tilt of the second mirror; and
the mirror is a facet mirror.

17. An optics unit, comprising:
a facet mirror comprising a plurality of individual mirrors,
wherein at least one of the individual mirrors comprises a mirror according to claim 1, and the optics unit is an illumination optics unit.

18. A system, comprising:
an illumination optics unit comprising a facet mirror which comprises a plurality of individual mirrors; and
a radiation source configured to generate illumination radiation,
wherein at least one of the individual mirrors comprises a mirror according to claim 1, and the system is an illumination system.

19. An apparatus, comprising:
an illumination optics unit comprising a facet mirror which comprises a plurality of individual mirrors; and
a projection optics unit,
wherein at least one of the individual mirrors comprises a mirror according to claim 1, and the apparatus is a projection exposure apparatus.

20. A method of using a projection exposure apparatus comprising an illumination optics unit and a projection optics unit, the method comprising:
using the illumination optics unit to illuminate an object in an object plane of the projection optics unit; and
using the projection optics unit to image the illuminated object into an image plane of the projection optics unit,
wherein the illumination optics unit comprises a mirror facet which comprises a plurality of individual mirrors, and at least one of the individual mirrors comprises a mirror according to claim 1.
